(19) United States
(12) Patent Application Publication
(10) Pub. No.: US 2026/0247604 A1
(43) Pub. Date: Aug. 20, 2026

(54) SEMICONDUCTOR DEVICES

(71) Applicant: SAMSUNG ELECTRONICS CO., LTD., Suwon-si (KR)

(72) Inventors: Boram GU, Suwon-si (KR); Jamin Koo, Suwon-si (KR); Jonghyeok Kim, Suwon-si (KR); Namgyu Woo, Suwon-si (KR); Harim Choi, Suwon-si (KR)

(73) Assignee: SAMSUNG ELECTRONICS CO., LTD., Suwon-si (KR)

(21) Appl. No.: 19/540,032

(22) Filed: Feb. 13, 2026

(30) Foreign Application Priority Data
Feb. 17, 2025 (KR) 10-2025-0020371

(51) Int. Cl. H10B 12/00; H10D 62/10

(52) U.S. Cl. CPC H10B 12/315; H10B 12/0335; H10D 62/115

(57) ABSTRACT

A semiconductor device includes an active pattern of a substrate, a gate structure in an upper portion of the active pattern, and a bit line structure on a central portion of the active pattern. The gate structure extends in a first direction parallel to an upper surface of the substrate. The bit line structure extends in a second direction parallel to the upper surface of the substrate and crosses the first direction. The bit line structure includes a conductive structure and an insulation structure on the conductive structure. An upper portion of the insulation structure is doped with impurities.

### CROSS-REFERENCE TO RELATED APPLICATION

This application claims priority under 35 U.S.C. § 119 to Korean Patent Application No. 10-2025-0020371 filed on February 17, 2025 in the Korean Intellectual Property Office, the contents of which being hereby incorporated by reference in its entirety.

### BACKGROUND

Example embodiments of the present disclosure relate to a semiconductor device.

A dynamic random access memory (DRAM) device may include, among other features, an active pattern and a contact plug structure on the active pattern. A portion of the contact plug structure may be formed by a selective epitaxial growth (SEG) process using an upper surface of the active pattern as a seed. In the event that the active pattern is covered, the active pattern may not serve as the seed in the SEG process, and thus, the contact plug structure may not be formed, and/or a contact resistance between the contact plug structure and the active pattern may increase.

### SUMMARY

Example embodiments provide a semiconductor device having improved characteristics.

According to an aspect of one or more example embodiments, a semiconductor device may comprise an active pattern of a substrate; a gate structure in an upper portion of the active pattern, the gate structure extending in a first direction parallel to an upper surface of the substrate; and a bit line structure on a central portion of the active pattern, the bit line structure extending in a second direction parallel to the upper surface of the substrate and crossing the first direction. The bit line structure may include a conductive structure; and an insulation structure on the conductive structure, an upper portion of the insulation structure being doped with impurities.

According to another aspect of one or more example embodiments, a semiconductor device may comprise an active pattern of a substrate, the substrate including a first region and a second region; a gate structure in an upper portion of the active pattern, the gate structure extending in a first direction parallel to an upper surface of the substrate; a bit line structure on a central portion of the active pattern, the bit line structure extending in a second direction parallel to the upper surface of the substrate and crossing the first direction; a lower contact plug structure contacting each of end portions of the active pattern; a first spacer structure on a first sidewall in the first direction of the bit line structure, the first spacer structure including a first spacer, a second spacer, and a third spacer that are sequentially stacked; and a second spacer structure on a second sidewall in the first direction of the bit line structure, the second spacer structure including a fourth spacer, a fifth spacer, and a sixth spacer that are sequentially stacked. Each of the first spacer and the second spacer may contact the lower contact plug structure, and each of the fourth spacer and the fifth spacer may contact the sixth spacer on the first region of the substrate.

According to yet another aspect of one or more example embodiments, a semiconductor device may comprise active patterns of a substrate, the active patterns being spaced apart from each other in each of a first direction and a second direction that are parallel to an upper surface of the substrate and that cross each other; gate structures each extending through first ones of the active patterns that are disposed in the first direction, the gate structures being spaced apart from each other in the second direction; bit line structures each extending in the second direction on central portions of second ones of the active patterns that are disposed in the second direction, and each of the bit line structures including a conductive structure and an insulation structure on the conductive structure; a first spacer structure and a second spacer structure on a first sidewall and a second sidewall, respectively, opposite to each other in the first direction of each of the bit line structures, each of the first spacer structure and the second spacer structure including an insulating material; a contact plug structure contacting each of end portions of each of the active patterns; and a capacitor on the contact plug structure. An upper portion of each of the first spacer structure and the second spacer structure and of an upper portion of each of the bit line structures may be doped with impurities.

### BRIEF DESCRIPTION OF THE DRAWINGS

FIGS. 1 to 3 are a plan view and cross-sectional views, respectively, illustrating a semiconductor device in accordance with example embodiments.

FIGS. 4 to 37 are plan views and cross-sectional views illustrating a method of manufacturing a semiconductor device in accordance with example embodiments.

### DETAILED DESCRIPTION

The above and other aspects and features of a semiconductor device and a method of forming the same in accordance with example embodiments will become readily understood from detail descriptions that follow, with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by the terms “first,” “second,” and/or “third”. Rather, the terms “first,” “second,” and/or “third” are only used to distinguish one material, layer (film), region, electrode, pad, pattern, structure and process from another material, layer (film), region, electrode, pad, pattern, structure and process. Thus, a “first” material, layer (film), region, electrode, pad, pattern, structure and process discussed below could be termed a “second” or a “third” material, layer (film), region, electrode, pad, pattern, structure and process without departing from the teachings of present disclosure.

Hereinafter, in the specification (but not necessarily in the claims), two directions that are substantially perpendicular to each other among horizontal directions, which are substantially parallel to an upper surface of a substrate, may be referred to as a first direction D1 and a second direction D2, and a direction substantially perpendicular to the upper surface of the substrate and having an acute angle with respect to the first direction D1 or the second direction D2 may be referred to as a third direction D3. A direction substantially perpendicular to the upper surface of the substrate may be referred to as a vertical direction.

Each of the first to third directions D1, D2 and D3 may refer not only to a direction shown in the drawings, but also to a direction opposite thereto.

A dynamic random access memory (DRAM) device may include an active pattern, a bit line structure, a spacer structure on a sidewall of the bit line structure, and a lower contact plug structure on the active pattern. The lower contact plug structure may include a first lower contact plug that may be formed by a selective epitaxial growth (SEG) process using an upper surface of the active pattern as a seed. In the event that the spacer structure covers the active pattern, the active pattern may not serve as the seed in the SEG process, and thus, the first lower contact plug may not be formed, and/or a contact resistance between the first lower contact plug and the active pattern may increase.

In the semiconductor device in accordance with various example embodiments, a contact area between the active pattern and the lower contact plug structure may increase so that a contact resistance therebetween may be reduced.

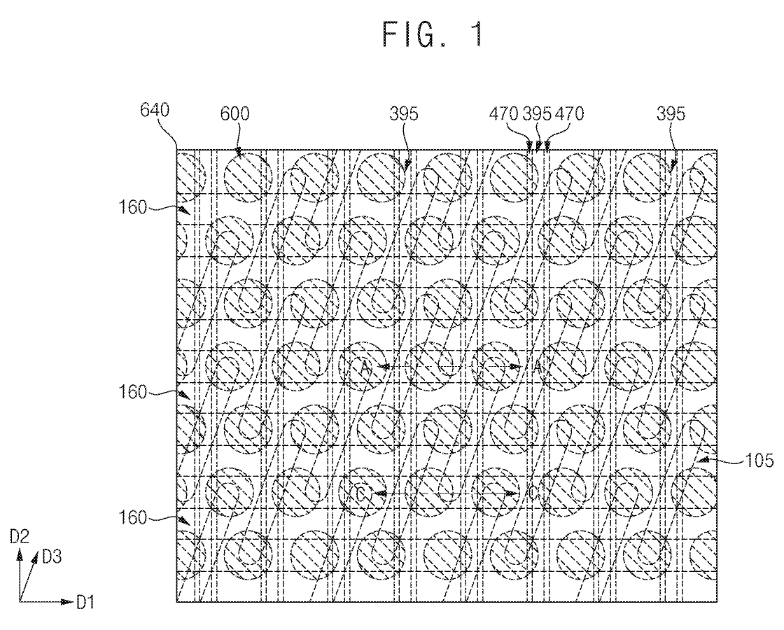

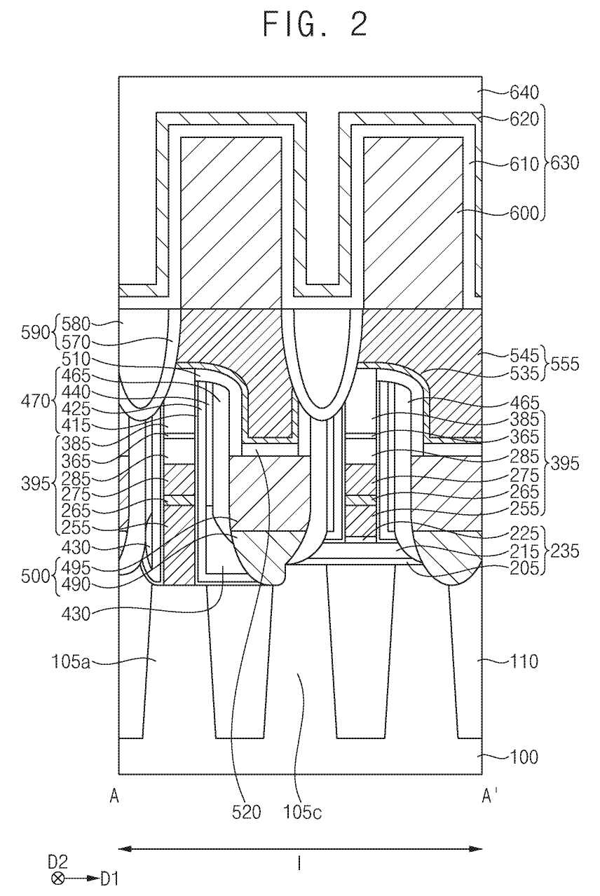

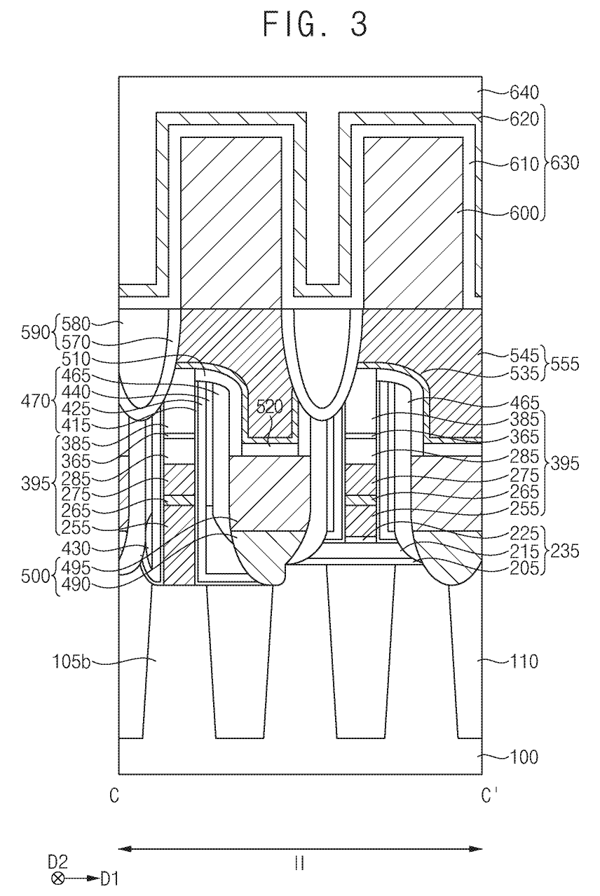

FIGS. 1 to 3 are a plan view and cross-sectional views, respectively, illustrating a semiconductor device in accordance with example embodiments. Specifically, FIG. 1 is the plan view, FIG. 2 is a cross-sectional view taken along line A-A’ of FIG. 1, and FIG. 3 is a cross-sectional view taken along line C-C’ of FIG. 1.

Referring to FIGS. 1 to 3, the semiconductor device may include an active pattern 105, a gate structure 160, a bit line structure 395, a contact plug structure and a capacitor structure on a substrate 100 including a first region I and a second region II.

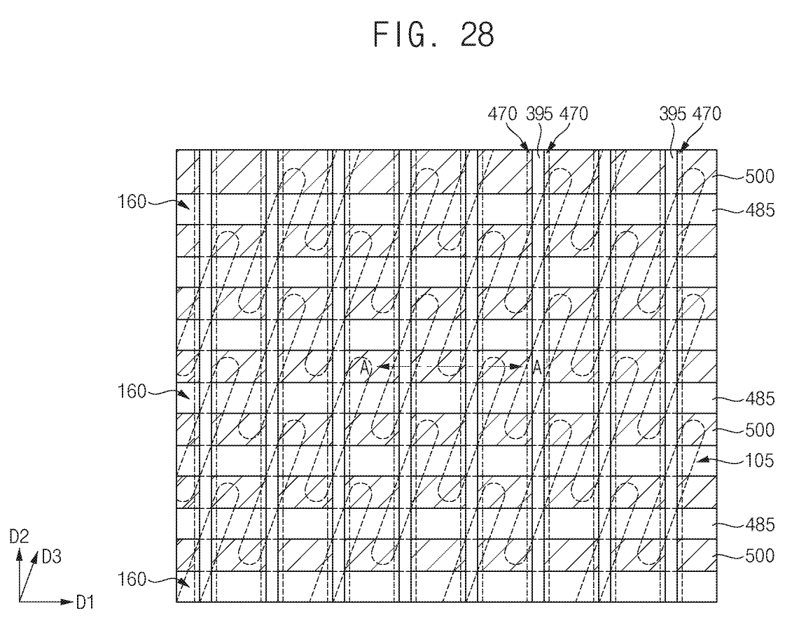

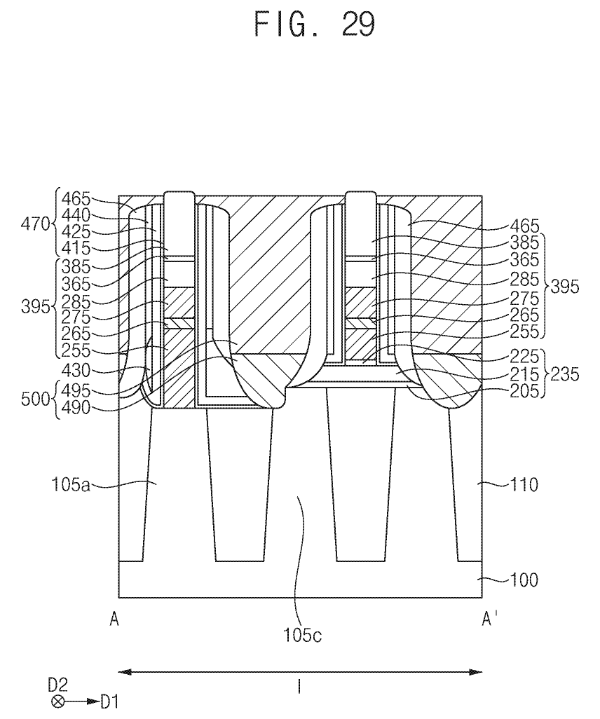

The semiconductor device may further include an isolation pattern 110, a spacer structure 470, a ninth spacer 510, a fourth insulation pattern 430, a second capping pattern 485 (refer to FIG. 28), a first insulation pattern structure 235, a second insulation pattern structure 590, and an ohmic contact pattern 520.

In example embodiments, the substrate 100 may include a semiconductor material, e.g., silicon, germanium, silicon-germanium, etc., or a III-V group compound semiconductor, e.g., GaP, GaAs, GaSb, etc. In example embodiments, the substrate 100 may be a silicon-on-insulator (SOI) substrate or a germanium-on-insulator (GOI) substrate.

A sidewall of the active pattern 105 may be covered by the isolation pattern 110. The active pattern 105 may extend in the third direction D3, and a plurality of active patterns 105 may be spaced apart from each other in each of the first and second directions D1 and D2. The active patterns 105 may include first active patterns 105a on the first region I of the substrate 100 and second active patterns 105b on the second region II of the substrate 100. Some of the second active patterns 105b adjacent to the first active pattern 105a in the first direction D1 may be referred to as third active patterns 105c.

In example embodiments, the active pattern 105 may include a material substantially the same as a material of the substrate 100, and the isolation pattern 110 may include an oxide, e.g., silicon oxide.

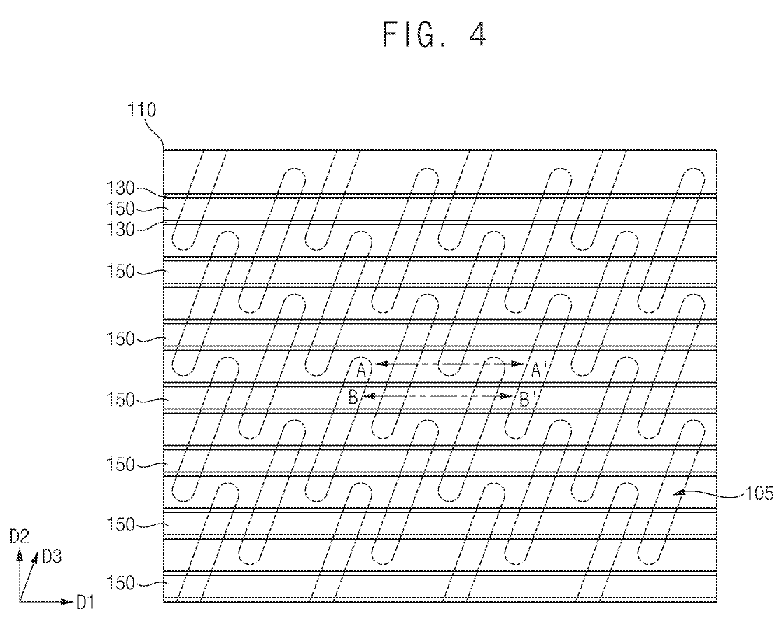

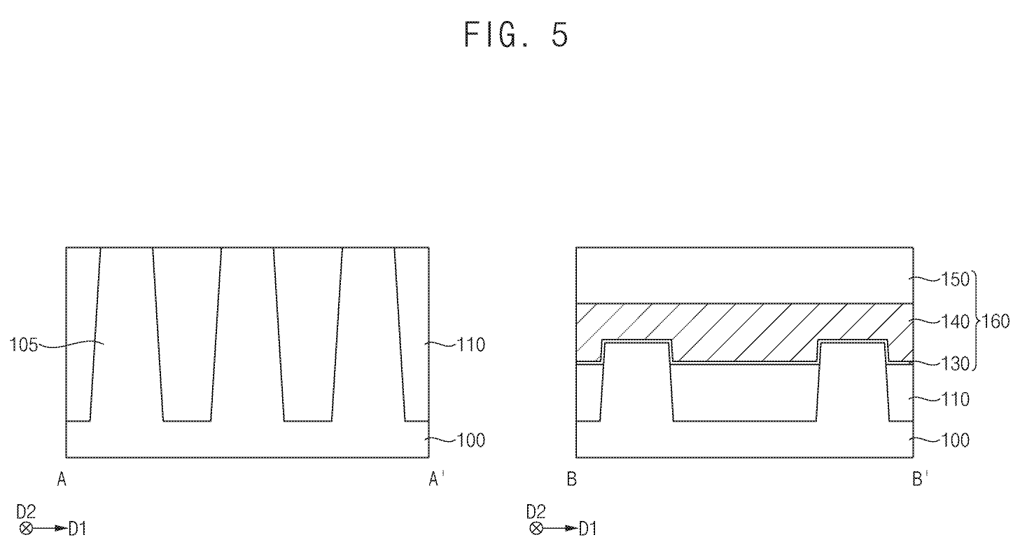

Referring to FIGS. 1 to 3 together with FIGS. 4 and 5, the gate structure 160 may be disposed in a second recess extending in the first direction D1 through upper portions of the active pattern 105 and the isolation pattern 110. The gate structure 160 may include a gate insulation pattern 130 on a bottom and a sidewall of the second recess, a gate electrode 140 on a portion of the gate insulation pattern 130 on the bottom and a lower sidewall of the second recess, and a gate mask 150 disposed on the gate electrode 140 and filling an upper portion of the second recess.

The gate insulation pattern 130 may include an oxide, e.g., silicon oxide, the gate electrode 140 may include a conductive material, e.g., a metal, a metal nitride, a metal silicide, etc., and the gate mask 150 may include an insulating nitride, e.g., silicon nitride.

In example embodiments, the gate structure 160 may extend in the first direction D1, and a plurality of gate structures 160 may be spaced apart from each other in the second direction D2.

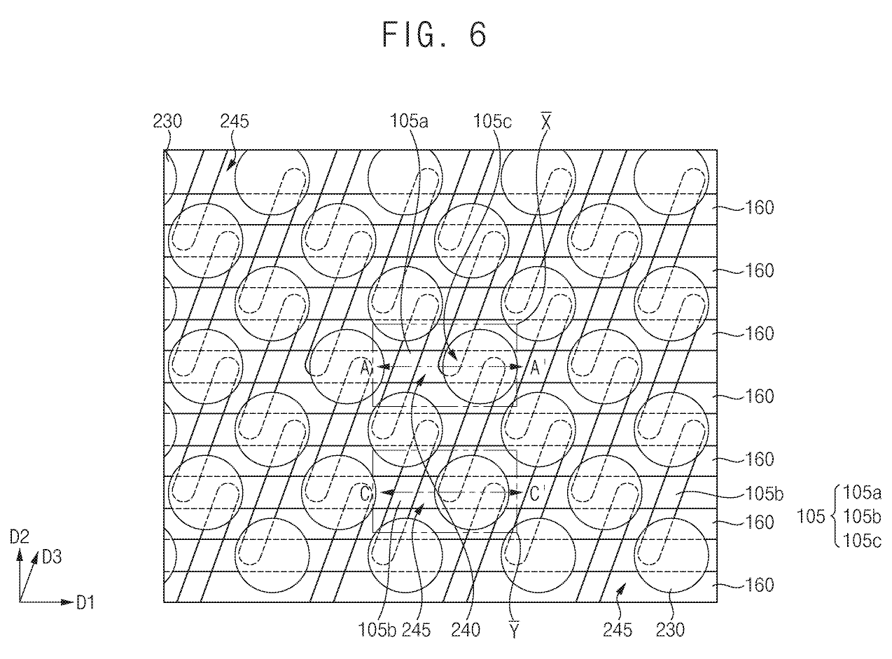

Referring to FIGS. 1 to 3 together with FIGS. 6 to 9, a first opening 240 may be formed through a portion of an insulation layer structure 230 on the first region I of the substrate 100 to expose upper surfaces of the first active pattern 105a, the isolation pattern 110 and the gate mask 150 of the gate structure 160, and a second opening 245 may be formed through a portion of the insulation layer structure 230 on the second region II of the substrate 100 to expose upper surfaces of the second active pattern 105b, the isolation pattern 110 and the gate mask 150 of the gate structure 160.

Each of the first and second openings 240 and 245 may expose an upper surface of a central portion of the active pattern 105 in the third direction D3.

In example embodiments, a bottom of the first opening 240 may be wider than an upper surface of a portion of the first active pattern 105a exposed by the first opening 240, and thus the first opening 240 may also expose an upper surface of a portion of the isolation pattern 110 adjacent to the first active pattern 105a, and may further expose an upper sidewall of the third active pattern 105c adjacent to the first active pattern 105a. Additionally, a bottom of the second opening 245 may be wider than an upper surface of a portion of the second active pattern 105b exposed by the second opening 245, and thus the second opening 245 may also expose an upper surface of a portion of the isolation pattern 110 adjacent to the second active pattern 105b.

In example embodiments, each of the first and second openings 240 and 245 may extend through the upper portions of the active pattern 105 and the isolation pattern 110, and thus the bottom of each of the first and second openings 240 and 245 may be lower than an upper surface of each of opposite edge portions of the active pattern 105 in the third direction D3.

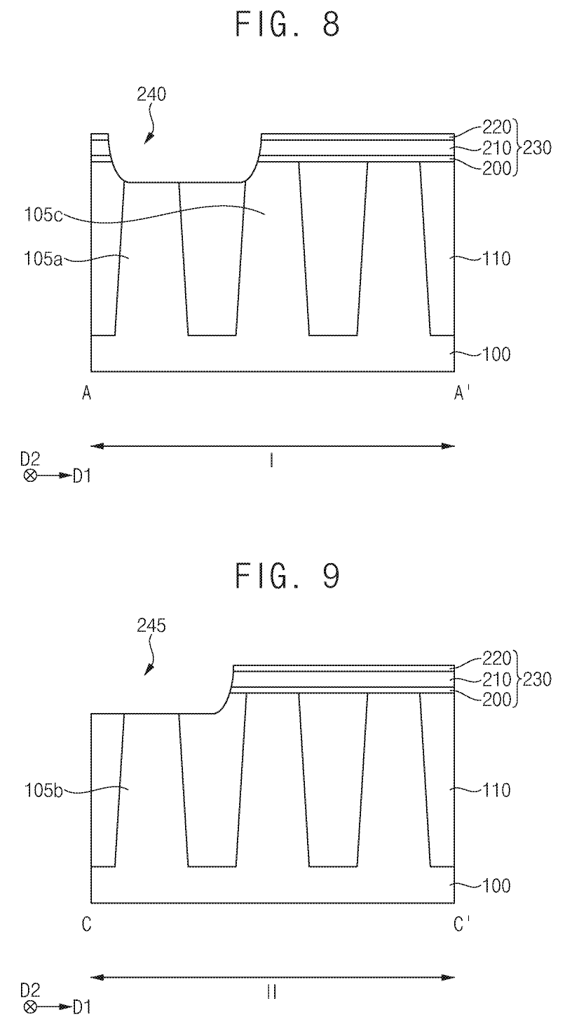

The first region I of the substrate 100 may be a region in which the first active pattern 105a and the first opening 240 are misaligned with each other, and the second region II of the substrate 100 may be a region in which the first active pattern 105a and the first opening 240 are aligned with each other. For example, a center of the first opening 240 in the first direction D1 may be misaligned with the first active pattern 105a so as not to correspond with a center of the first active pattern 105a, whereas a center of the second opening 245 may be aligned with the second active pattern 105b so as to correspond with a center of the second active pattern 105b, as illustrated in FIGS. 8-9. In example embodiments, an area of the first region I of the substrate 100 may be about 35% of a total area of the substrate 100.

Returning to FIGS. 2 and 3, the bit line structure 395 may include a first conductive pattern 255, a first barrier pattern 265, a second conductive pattern 275, a first mask 285, a first etch stop pattern 365 and a first capping pattern 385 sequentially stacked in the vertical direction on the first and second openings 240 and 245 or the first insulation pattern structure 235. The first conductive pattern 255, the first barrier pattern 265 and the second conductive pattern 275 may collectively form a conductive structure, and the first mask 285, the first etch stop pattern 365 and the first capping pattern 385 may collectively form an insulation structure.

The first conductive pattern 255 may include, e.g., doped polysilicon, the first barrier pattern 265 may include a metal nitride, e.g., titanium nitride, or a metal silicon nitride, e.g., titanium silicon nitride, the second conductive pattern 275 may include a metal, e.g., tungsten, and each of the first mask 285, the first etch stop pattern 365 and the first capping pattern 385 may include an insulating nitride, e.g., silicon nitride. An upper portion of the first capping pattern 385 may include impurities, e.g., phosphorus, arsenic, silicon, etc., which may be implanted or doped into the upper portion of the first capping pattern 385.

In example embodiments, the bit line structure 395 may extend in the second direction D2 on the substrate 100, and a plurality of bit line structures 395 may be spaced apart from each other in the first direction D1.

The spacer structure 470 may include a first spacer 415, a second spacer 425, a third spacer 440, and a fourth spacer 465 sequentially stacked on a sidewall of the bit line structure 395 in the first direction D1. The first spacer 415 may cover a portion of the sidewall of the bit line structure 395 in the first direction D1 and portions of the upper surfaces of the active pattern 105 and the isolation pattern 110, and the second spacer 425 may cover an outer sidewall of the first spacer 415. The third spacer 440 may cover an upper outer sidewall of the second spacer 425, and the fourth spacer 465 may cover an outer sidewall of the third spacer 440. An upper surface of the spacer structure 470 may be lower than an upper surface of the bit line structure 395.

In example embodiments, the spacer structures 470 on the opposite sidewalls, respectively, of the bit line structure 395 in the first direction D1 may form and be referred to as a first spacer structure and a second spacer structure, respectively. In other words, the first spacer structure may correspond to the spacer structure 470 on a first sidewall of the bit line structure 395 in the first direction D1 and may include a first spacer, a second spacer, a third spacer, and a fourth spacer that correspond respectively to the first spacer 415, the second spacer 425, the third spacer 440, and the fourth spacer 465 described above, and the second spacer structure may correspond to the spacer structure 470 on a second sidewall of the bit line structure 395 and may include a fifth spacer, a sixth spacer, a seventh spacer, and an eighth spacer which correspond respectively to the first spacer 415, the second spacer 425, the third spacer 440, and the fourth spacer 465 described above. In example embodiments, the spacer structures 470 on the opposite sidewalls, respectively, of the bit line structure 395 in the first direction D1 on the first region I of the substrate 100 may have an asymmetric shape with respect to the bit line structure 395.

In example embodiments, on the first region I of the substrate 100, a lower portion of a first one of the spacer structures 470 on a first sidewall of the bit line structure 395 in the first direction D1 may have a maximum width in the first direction D1 that is greater than a maximum width in the first direction D1 of a lower portion of a second one of the spacer structures 470 on a second sidewall of the bit line structure 395 in the first direction D1. Particularly, lower portions of first ones of the first and second spacers 415 and 425 on the first sidewall of the bit line structure 395 in the first direction D1 may have a maximum width in the first direction D1 that is greater than a maximum width in the first direction D1 of lower portions of second ones of the first and second spacers 415 and 425 on the second sidewall of the bit line structure 395 in the first direction D1.

In example embodiments, the spacer structures 470 on the opposite sidewalls, respectively, of the bit line structure 395 in the first direction D1 on the second region II of the substrate 100 may have a symmetric shape with respect to the bit line structure 395.

In example embodiments, on the second region II of the substrate 100, a lower portion of a first one of the spacer structures 470 on a first sidewall of the bit line structure 395 in the first direction D1 may have a maximum width in the first direction D1 that is substantially equal to a maximum width in the first direction D1 of a lower portion of a second one of the spacer structures 470 on a second sidewall of the bit line structure 395 in the first direction D1.

The ninth spacer 510 may be disposed on an upper sidewall of the first capping pattern 385 of the bit line structure 395, and may cover an upper portion of the spacer structure 470.

Each of the first, fourth and fifth spacers 415, 465 and 510 may include an insulating nitride, e.g., silicon nitride, and each of the second and third spacers 425 and 440 may include an oxide, e.g., silicon oxide. The fourth spacer 465 may include a high-density insulating nitride compared to the first spacer 415, and the second spacer 425 may include a high-density oxide compared to the third spacer 440. In an example embodiment, the third spacer 440 may be an air gap, and thus may include air. A lower portion of each of the first, second and fourth spacers 415, 425 and 465 may include the impurities included in the first capping pattern 385.

The first insulation pattern structure 235 may be disposed under the bit line structure 395 on the active pattern 105 and the isolation pattern 110, and may include a first insulation pattern 205, a second insulation pattern 215, and a third insulation pattern 225 sequentially stacked in the vertical direction. Each of the first and third insulation patterns 205 and 225 may include an oxide, e.g., silicon oxide, and the second insulation pattern 215 may include an insulating nitride, e.g., silicon nitride.

The fourth insulation pattern 430 may be disposed in each of the first and second openings 240 and 245, and may contact a lower sidewall of the second spacer 425, a lower surface of the third spacer 440, and a lower inner sidewall of the fourth spacer 465. The fourth insulation pattern 430 may include an insulating nitride, e.g., silicon nitride. A lower portion of the fourth insulation pattern 430 may include the impurities.

The contact plug structure may include a lower contact plug structure 500, the ohmic contact pattern 520 and an upper contact plug 555 sequentially stacked in the vertical direction on the active pattern 105 and the isolation pattern 110.

The lower contact plug structure 500 may include a first lower contact plug 490 and a second lower contact plug 495 stacked in the vertical direction. The first lower contact plug 490 may contact a portion of the upper surface of each of opposite edge portions of the active pattern 105 in the third direction D3 and a portion of the isolation pattern 110 adjacent thereto, and the second lower contact plug 495 may contact an upper surface of the first lower contact plug 490 and an outer sidewall of the fourth spacer 465.

On the first region I of the substrate 100, the first lower contact plug 490 may contact the lower portion of the first one of the spacer structures 470 on the first sidewall of the bit line structure 395, that is, the lower portions of the first ones of the first and second spacers 415 and 425, and may further contact lower portions of the fourth insulation pattern 430 and the first spacer 465 on the first sidewall of the bit line structure 395 and a lower portion of the fourth spacer 465 on second sidewall of the bit line structure 395, however, not the first to third spacers 415, 425 and 440 and the fourth insulation pattern 430 on the second sidewall of the bit line structure 395.

On the second region II of the substrate 100, the first lower contact plug 490 may contact lower portions of the first, second and fourth spacers 415, 425 and 465 and the fourth insulation pattern 430 on each of the sidewalls of the bit line structure 395.

In example embodiments, a plurality of lower contact plug structures 500 may be spaced apart from each other in the second direction D2 between neighboring ones of the bit line structures 395 in the first direction D1, and the second capping pattern 485 may be disposed between neighboring ones of the lower contact plug structures 500 in the second direction D2.

In example embodiments, the first lower contact plug 490 may include, e.g., single crystalline silicon doped with impurities, the second lower contact plug 495 may include, e.g., amorphous silicon doped with impurities, and the second capping pattern 485 may include an insulating nitride, e.g., silicon nitride.

The ohmic contact pattern 520 may partially cover an upper surface of the second lower contact plug 495, and may include a metal silicide, e.g., titanium silicide, cobalt silicide, nickel silicide, etc.

The upper contact plug 555 may include a second metal pattern 545 and a second barrier pattern 535 covering a lower surface of the second metal pattern 545. The second barrier pattern 535 may partially cover upper surfaces of the ohmic contact pattern 520, the ninth spacer 510 and the bit line structure 395, and the second metal pattern 545 may contact an upper surface of the second barrier pattern 535. In example embodiments, the second metal pattern 545 may include a metal, e.g., tungsten, and the second barrier pattern 535 may include a metal nitride, e.g., titanium nitride.

In example embodiments, a plurality of upper contact plugs 555 may be spaced apart from each other in each of the first and second directions D1 and D2, and may be arranged in a honeycomb pattern or a lattice pattern in a plan view. Each of the upper contact plugs 555 may have a shape of, e.g., a circle, an ellipse or a polygon.

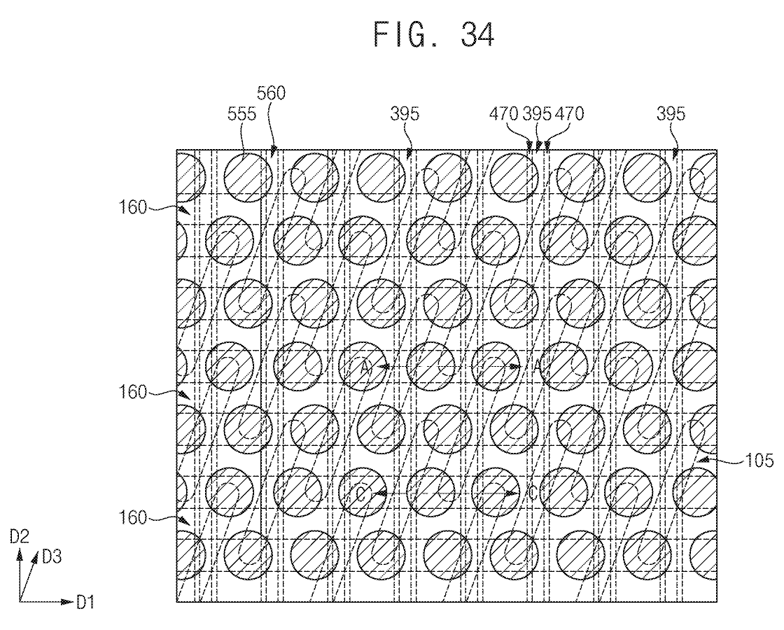

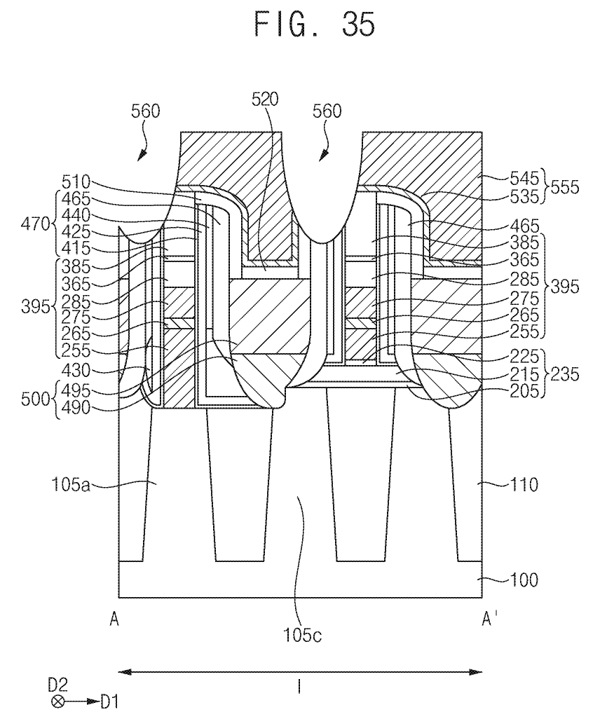

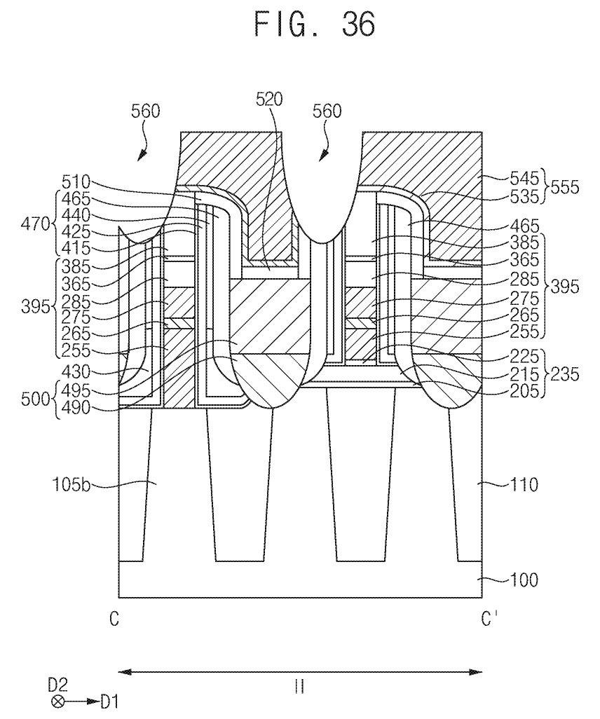

Referring to FIGS. 1 to 3 together with FIGS. 34 to 36, the second insulation pattern 590 may include a fifth insulation pattern 570 and a sixth insulation pattern 580.

The fifth insulation pattern 570 may be disposed on an inner wall of an eighth opening 560 that may extend partially through the upper contact plug 555, the insulation structure of the bit line structure 395, and the first to fourth spacers 415, 425, 440 and 465 and surround the upper contact plug 555 in a plan view. The sixth insulation pattern 580 may be disposed on the fifth insulation pattern 570, and may fill a remaining portion of the eighth opening 560.

Each of the fifth and sixth insulation patterns 570 and 580 may include an insulating nitride, e.g., silicon nitride.

The capacitor structure may include a capacitor 630 and a plate electrode 640 on the capacitor 630, and the capacitor 630 may include a first capacitor electrode 600 and a second capacitor electrode 620 and a dielectric pattern 610 therebetween. The first capacitor electrode 600 may be disposed on the upper contact plug 555, the dielectric pattern 610 may be disposed on an upper surface and a sidewall of the first capacitor electrode 600 and an upper surface of the second insulation pattern structure 590, and the second capacitor electrode 620 may be disposed on the dielectric pattern 610.

Since the plurality of upper contact plugs 555 are spaced apart from each other in each of the first and second directions D1 and D2, a plurality of first capacitor electrodes 600 may be spaced apart from each other in each of the first and second directions D1 and D2.

In example embodiments, the first capacitor electrode 600 may have a shape of, e.g., a circle, an ellipse, a polygon, a polygon with rounded corners, etc., in a plan view. In some example embodiments, the first capacitor electrodes 600 may be arranged in a honeycomb pattern or a lattice pattern in a plan view.

Each of the first and second capacitor electrodes 600 and 620 may include a metal, e.g., titanium, tantalum, etc., a metal nitride, e.g., titanium nitride, tantalum nitride, etc., or a metal silicide, and the dielectric pattern 610 may include, e.g., a metal oxide.

The plate electrode 640 may be disposed on the second capacitor electrode 620, and may include, e.g., doped or undoped silicon-germanium.

As illustrated above, the lower contact plug in the semiconductor device may include the first and second lower contact plugs 490 and 495 sequentially stacked, and the first lower contact plug 490 may be formed by a selective epitaxial growth (SEG) process using the active pattern 105 as a seed, as is describe below, so as to include, e.g., single crystalline silicon. Thus, a contact resistance between the first lower contact plug 490 and the active pattern 105 may be reduced, so that the semiconductor device may have enhanced electric characteristics.

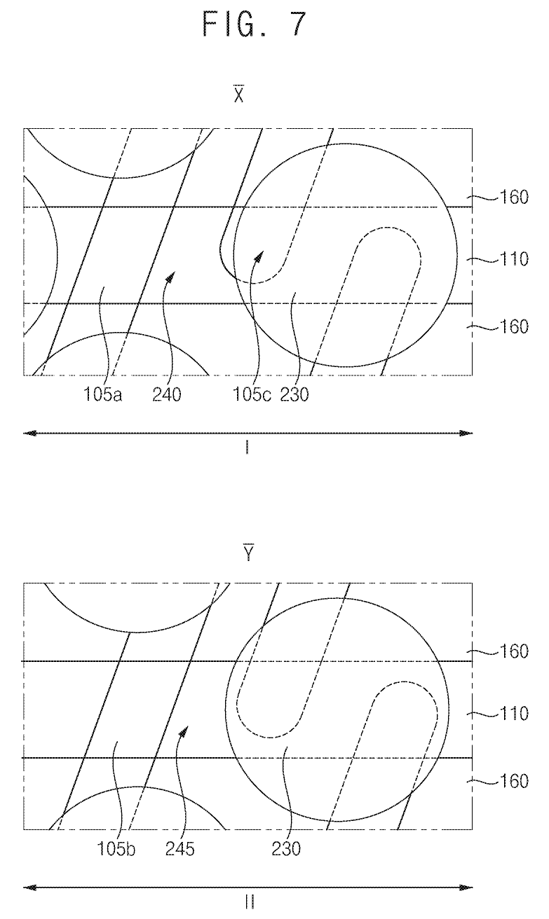

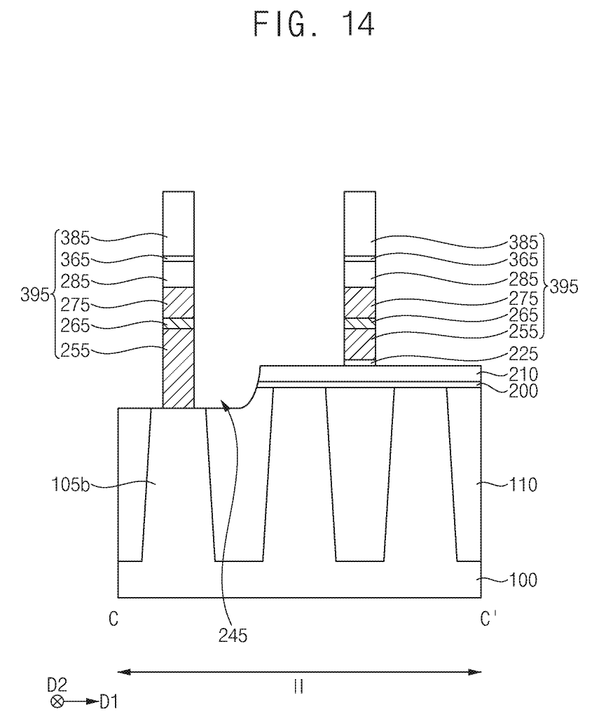

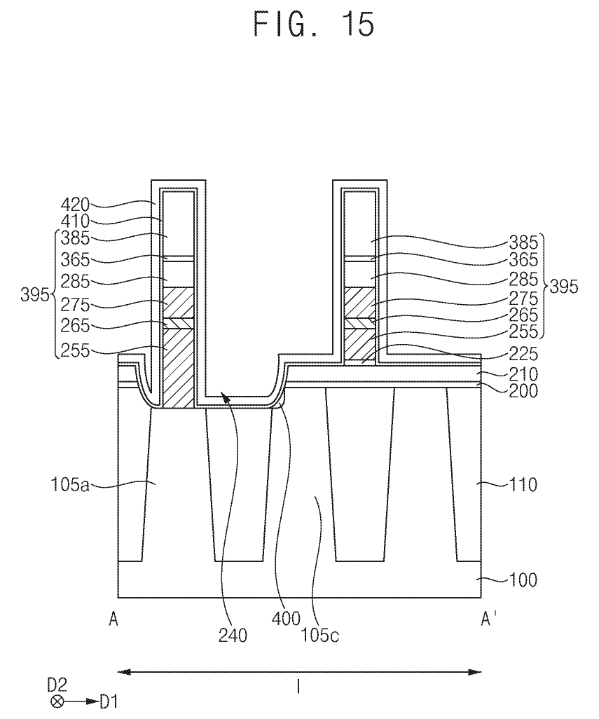

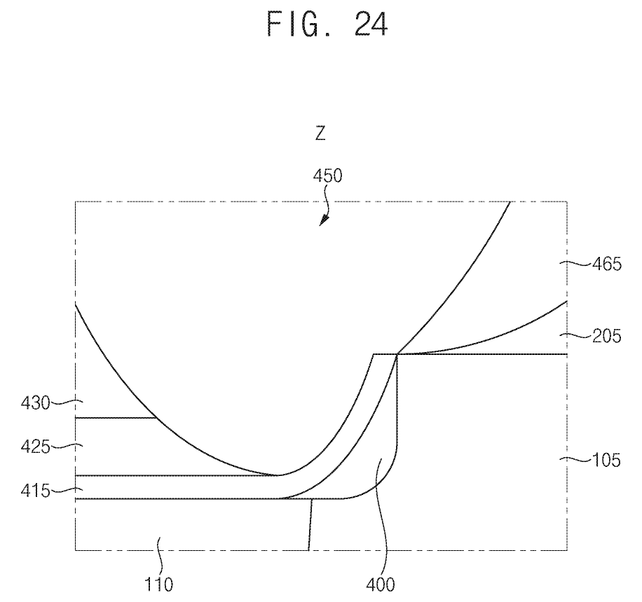

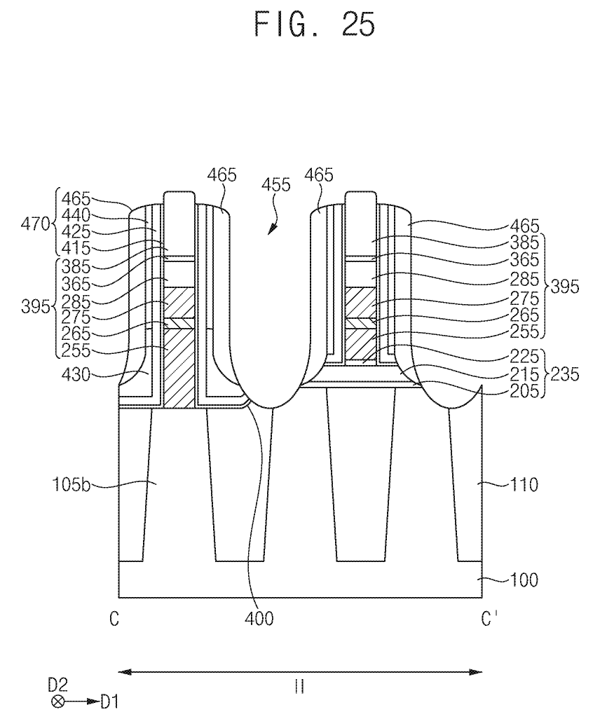

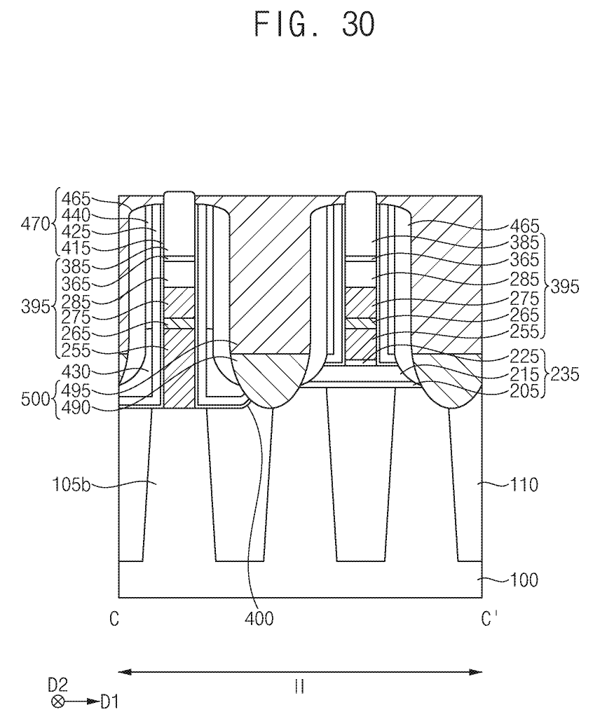

FIGS. 4 to 37 are plan views and cross-sectional views illustrating a method of manufacturing a semiconductor device in accordance with example embodiments. Particularly, FIGS. 4, 6, 12, 28 and 34 are the plan views, FIG. 5 includes cross-sectional views taken along lines A-A’ and B-B’ of FIG. 1, FIG. 7 includes enlarged cross-sectional views of regions X and Y of FIG. 6, FIG. 8, 10, 13, 15, 17, 19, 21, 23, 26, 27, 29, 31, 33, 35 and 37 are cross-sectional views taken along lines A-A’ of corresponding plan views, respectively, and FIGS. 9, 11, 14, 16, 18, 20, 22, 25, 30, 32 and 36 are cross-sectional views taken along line C-C’ of corresponding plan views, respectively.

Referring to FIGS. 4 and 5, an upper portion of a substrate 100 may be removed to form a first recess, and an isolation pattern 110 may be formed in the first recess.

Since the first recess is formed in the substrate 100, an active pattern 105 may be defined in the substrate 100, and a sidewall of the active pattern 105 may be covered by the isolation pattern 110.

In example embodiments, the active pattern 105 may extend in the third direction D3, and a plurality of active patterns 105 may be formed to be spaced apart from each other in each of the first and second directions D1 and D2.

The active pattern 105 and the isolation pattern 110 on the substrate 100 may be partially etched to form a second recess extending in the first direction D1, and a gate structure 160 including a gate insulation pattern 130, a gate electrode 140 and a gate mask 150 sequentially stacked may be formed in the second recess. In example embodiments, the gate structure 160 may extend in the first direction D1, and a plurality of gate structures 160 may be spaced apart from each other in the second direction D2.

Referring to FIGS. 6 to 9, an insulation layer structure 230 may be formed on the active pattern 105, the isolation pattern 110 and the gate structure 160.

The insulation layer structure 230 may include a first insulation layer 200, a second insulation layer 210, and a third insulation layer 220 sequentially stacked.

A patterning process may be performed on the insulation layer structure 230, and the active pattern 105, the isolation pattern 110, and the gate mask 150 of the gate structure 160 may be partially etched by an etching process using the patterned insulation layer structure 230 as an etching mask to form an opening. In example embodiments, the insulation layer structure 230 remaining after the etching process may have a shape of, e.g., a circle or an ellipse in a plan view, and a plurality of insulation layer structures 230 may be spaced apart from each other in each of the first and second directions D1 and D2.

Hereinafter, ones of the openings that are formed on the first region I of the substrate 100 may be referred to as first openings 240, and ones of the openings that are formed on the second region II of the substrate 100 may be referred to as second openings 245. Additionally, ones of the active patterns 105 of which central portions in the third direction D3 are exposed by the first openings 240, respectively, may be referred to as first active patterns 105a, and ones of the active patterns 105 of which central portions in the third direction D3 are exposed by the second openings 245, respectively, may be referred to as second active patterns 105b. One of the second active patterns 105b that is adjacent to the first active pattern 105a in the first direction D1 and has a sidewall partially exposed by the first opening 240 may be referred to as a third active pattern 105c.

Thus, the first opening 240 may expose an upper surface of the first active pattern 105a, a first sidewall of the third active pattern 105c and a portion of the isolation pattern 110 adjacent to the first active pattern 105a, and the second opening 245 may expose an upper surface of the second active pattern 105b and a portion of the isolation pattern 110 adjacent to the second active pattern 105b.

Each of the insulation layer structures 230 may overlap in the vertical direction end portions in the third direction D3 of neighboring active patterns 105 facing each other in the first direction D1, and during the patterning process, misalignment may occur on the first region I of the substrate 100. Thus, the insulation layer structure 230 on the first region I of the substrate 100 may partially overlap the third active pattern 105c in the vertical direction, and the first opening 240 may expose the first sidewall of the third active pattern 105c. During the patterning process, misalignment may not occur on the second region II of the substrate 100, and each of the insulation layer structures 230 may overlap in the vertical direction end portions in the third direction D3 of neighboring active patterns 105 facing each other in the first direction D1.

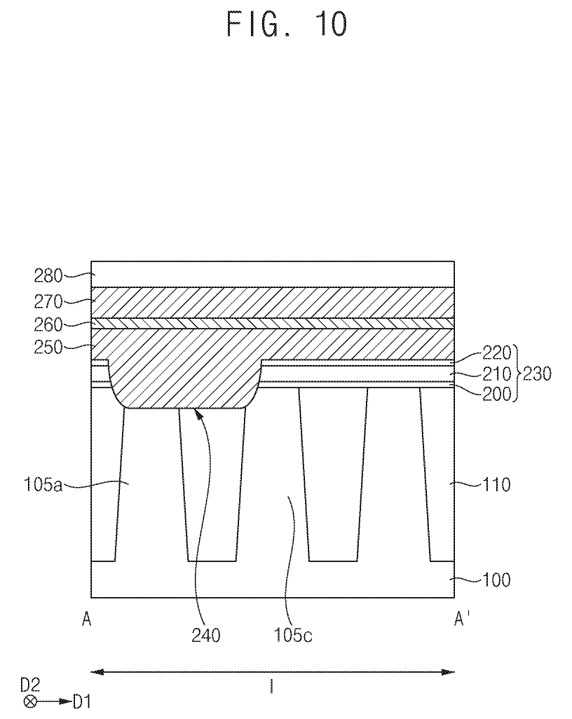

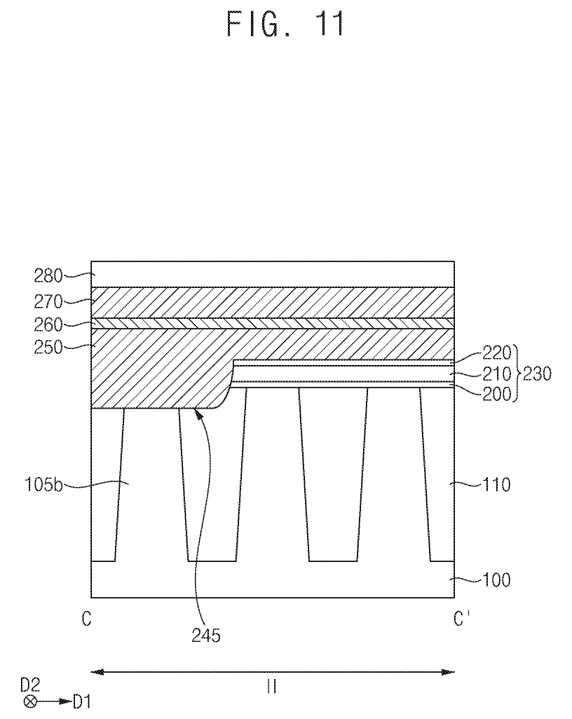

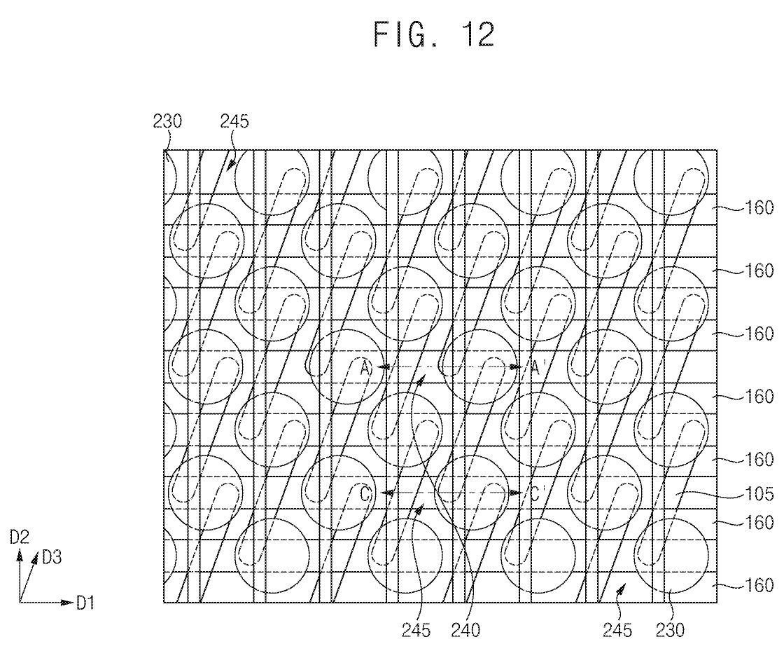

Referring to FIGS. 10 and 11, a first conductive layer 250, a first barrier layer 260, a second conductive layer 270 and a first mask layer 280 may be sequentially stacked on the insulation layer structure 230, the first active pattern 105a exposed by the first opening 240, the second active pattern 105b exposed by the second opening 245, the isolation pattern 110 and the gate structure 160, which may collectively form a conductive layer structure.

The first conductive layer 250 may fill each of the first and second openings 240 and 245.

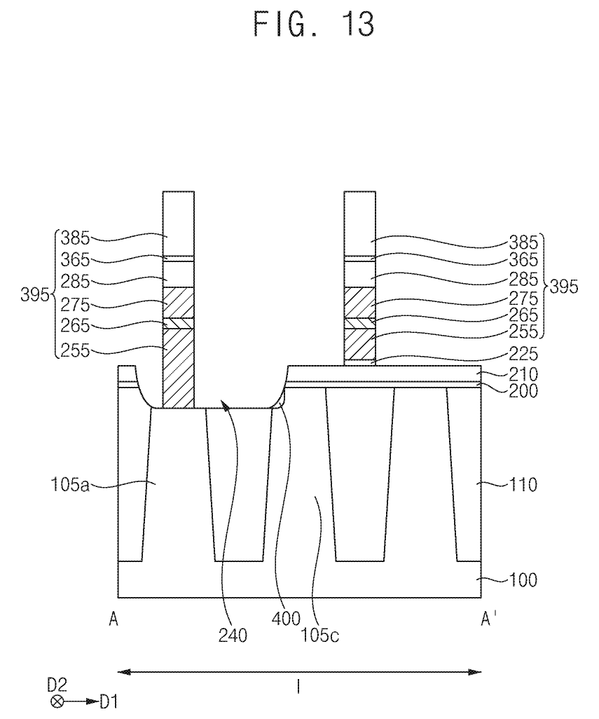

Referring to FIGS. 12 to 14, a first etch stop layer and a first capping layer may be sequentially stacked on the conductive layer structure, and the first capping layer may be etched to form a first capping pattern 385.

An etching process may be performed using the first capping pattern 385 as an etching mask on the first etch stop layer, the first mask layer 280, the second conductive layer 270, the first barrier layer 260 and the first conductive layer 250.

In example embodiments, the first capping pattern 385 may extend in the second direction D2, and a plurality of first capping patterns 385 may be spaced apart from each other in the first direction D1.

By the etching process, a first conductive pattern 255, a first barrier pattern 265, a second conductive pattern 275, a first mask 285, a first etch stop pattern 365 and the first capping pattern 385 may be formed so as to be sequentially stacked on each of the first and second openings 240 and 245, and a third insulation pattern 225, the first conductive pattern 255, the first barrier pattern 265, the second conductive pattern 275, the first mask 285, the first etch stop pattern 365 and the first capping pattern 385 may be formed so as to be sequentially stacked on the third insulation layer 210 of the insulation layer structure 230 at an outside of the first and second openings 240 and 245.

Hereinafter, the first conductive pattern 255, the first barrier pattern 265, the second conductive pattern 275, the first mask 285, the first etch stop pattern 365 and the first capping pattern 385 sequentially stacked may be referred to as a bit line structure 395. The first conductive pattern 255, the first barrier pattern 265 and the second conductive pattern 275 may collectively form a conductive structure, and the first mask 285, the first etch stop pattern 365 and the first capping pattern 385 may collectively form an insulation structure. In example embodiments, the bit line structure 395 may extend in the second direction D2 on the substrate 100, and a plurality of bit line structures 395 may be spaced apart from each other in the first direction D1.

The first sidewall of the third active pattern 105c exposed by the first opening 240 may be oxidized to form an oxide layer 400. The active pattern 105 may include a material substantially the same as that of the substrate 100, e.g., a semiconductor material such as silicon, and the oxide layer 400 may include, e.g., silicon oxide.

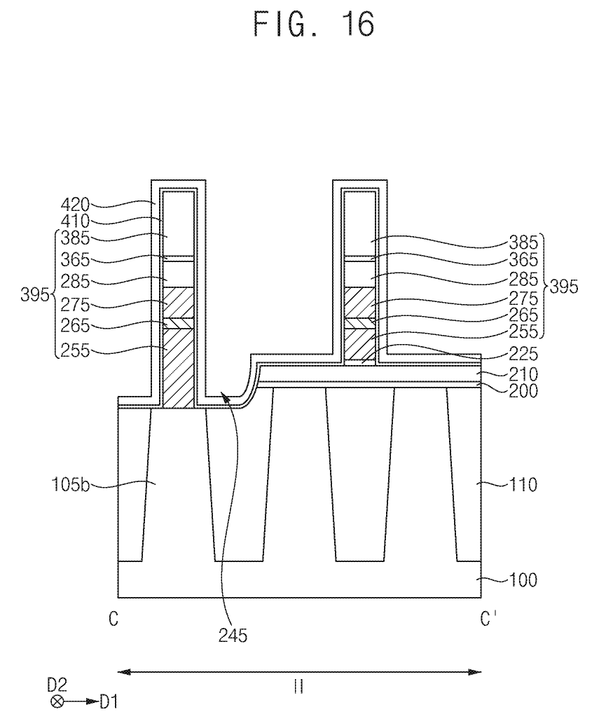

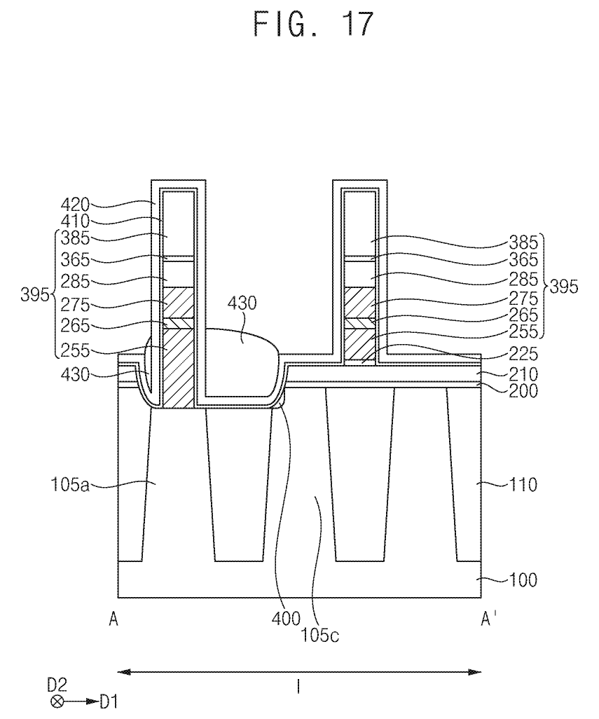

Referring to FIGS. 15 and 16, a first spacer layer 410 and a second spacer layer 420 may be sequentially formed on the substrate 100 having the bit line structure 395.

The first spacer layer 410 may be formed to cover the bit line structure 395, the first active pattern 105a, the portion of the isolation pattern 110 and the oxide layer 400 exposed by the first opening 240, the second active pattern 105b and the portion of the isolation pattern 110 exposed by the second opening 245, the first and second insulation layers 200 and 210, and the third insulation pattern 225. The second spacer layer 420 may be formed on a surface of the first spacer layer 410.

In example embodiments, the first spacer layer 410 may include an insulating nitride, e.g., silicon nitride, and the second spacer layer 420 may include an oxide, e.g., silicon oxide.

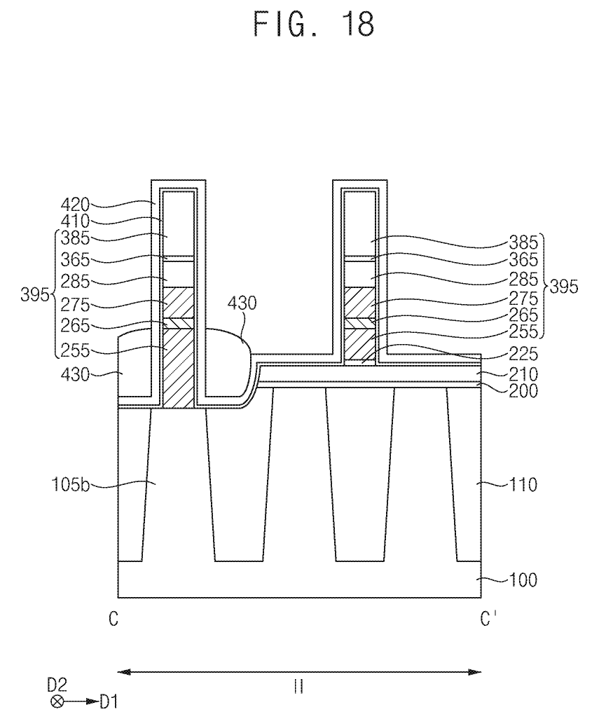

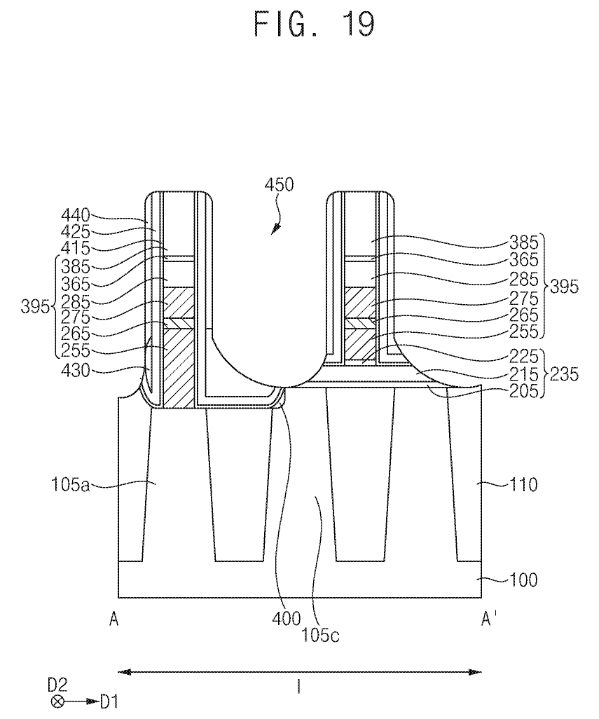

Referring to FIGS. 17 and 18, a fourth insulation layer may be formed on the second spacer layer 420 to fill remaining portions of the first and second openings 240 and 245, and the fourth insulation layer may be etched by an etching process.

In example embodiments, the etching process may be performed by a wet etching process using an etching solution, e.g., H₂PO₃, SC1, HF, etc., and portions of the fourth insulation layer at the outside of the first and second openings 240 and 245 may be removed. Thus, a portion of the second spacer layer 420 at the outside of the first and second openings 240 and 245 may be exposed, and portions of the fourth insulation layer in each of the first and second openings 240 and 245 may form a fourth insulation pattern 430.

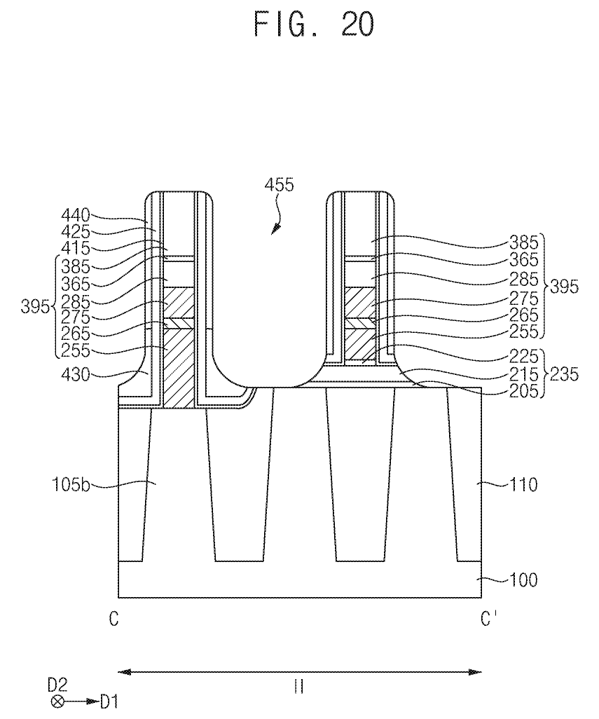

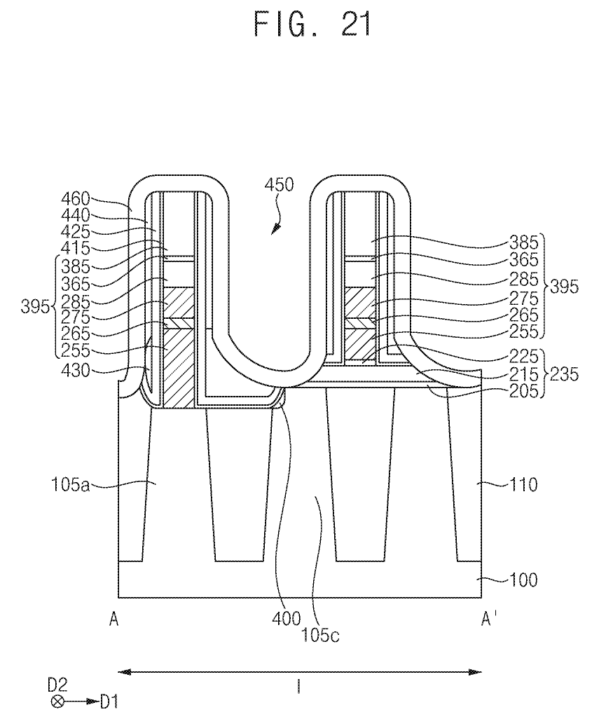

Referring to FIGS. 19 and 20, a third spacer layer may be formed on the exposed surface of the second spacer layer 420 and the fourth insulation patterns 430, and may be anisotropically etched to form a third spacer 440 on the exposed surface of the second spacer layer 420 and the fourth insulation pattern 430 to cover a sidewall of the bit line structure 395.

A dry etching process may be performed using the first capping pattern 385 and the third spacer 440 as an etching mask to form a third opening 450 partially exposing an upper surface of the third active pattern 105c on the first region I of the substrate 100, and a fourth opening 455 partially exposing an upper surface of second active pattern 105b on the second region II of the substrate 100

By the dry etching process, portions of the first and second spacer layers 410 and 420 on upper surfaces of the first capping pattern 385 and the third insulation layer 210 may be removed, and thus a first spacer 415 and a second spacer 425 covering a sidewall of the bit line structure 395 may be formed. By the dry etching process, the second and third insulation layers 200 and 210 may also be partially etched so that second and third insulation patterns 205 and 215 may remain under the bit line structure 395. The second to fourth insulation patterns 205, 215 and 225 sequentially stacked under the bit line structure 395 may collectively form a first insulation pattern structure 235.

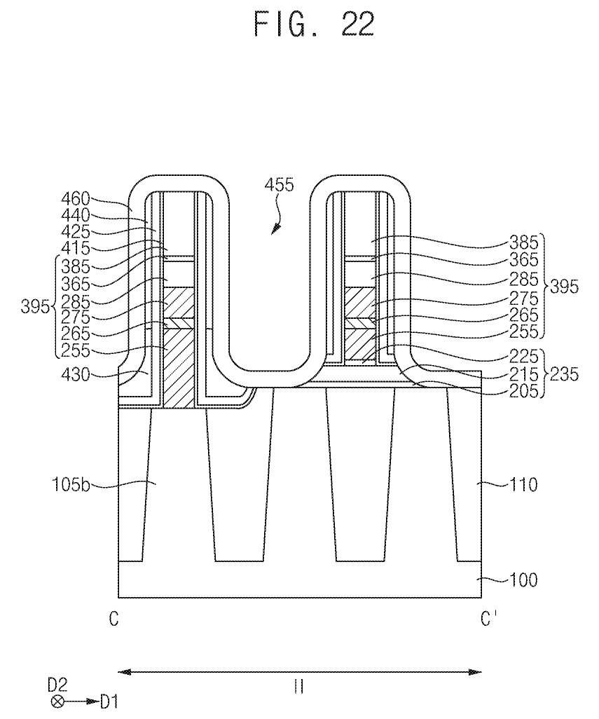

Referring to FIGS. 21 and 22, a fourth spacer layer 460 may be formed on upper surfaces of the first capping pattern 385 and the first and second spacers 415 and 425, an upper surface and an outer sidewall of the third spacer 440, a portion of an upper surface of the fourth insulation pattern 430, the third active pattern 105c and the gate mask 150 exposed by the third opening 450, and the second active pattern 105b, the isolation pattern 110 and the gate mask 150 exposed by the fourth opening 455.

The fourth spacer layer 460 may include an insulating nitride, e.g., silicon nitride.

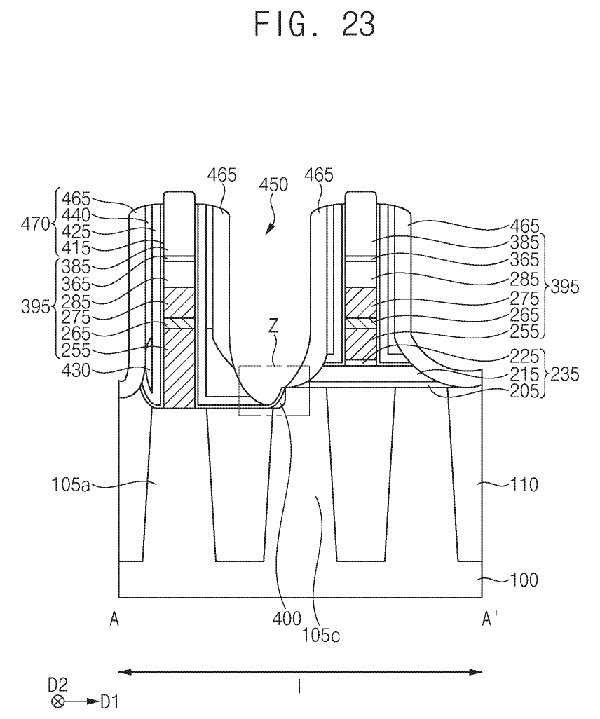

Referring to FIGS. 23 to 25, the fourth spacer layer 460 may be etched by an anisotropic etching process to form a fourth spacer 465 on the sidewall of the bit line structure 395, and the first to fourth spacers 415, 425, 440 and 465 sequentially stacked on the sidewall of the bit line structure 395 may collectively form a spacer structure 470.

During the anisotropic etching process, upper portions of the first capping pattern 385 and the first to third spacers 415, 425 and 440 may be partially removed. The first capping pattern 385 may have a high etching selectivity compared to the first to third spacers 415, 425 and 440, and thus an upper surface of the spacer structure 470 may be lower than the upper surface of the first capping pattern 385.

By the anisotropic etching process, each of the third and fourth openings 450 and 455 may be enlarged downwardly in the vertical direction. Thus, the third opening 450 may expose an outer sidewall of the fourth spacer 465, a sidewall of the fourth insulation pattern 430, a lower sidewall of the second spacer 425 and a lower portion of the first spacer 415, and the fourth opening 455 may partially expose the outer sidewall of the fourth spacer 465 and the upper surfaces of the isolation pattern 110 and the active pattern 105. The oxide layer 400 on the first region I of the substrate 100 may be covered by the first spacer 415, and thus may not be removed.

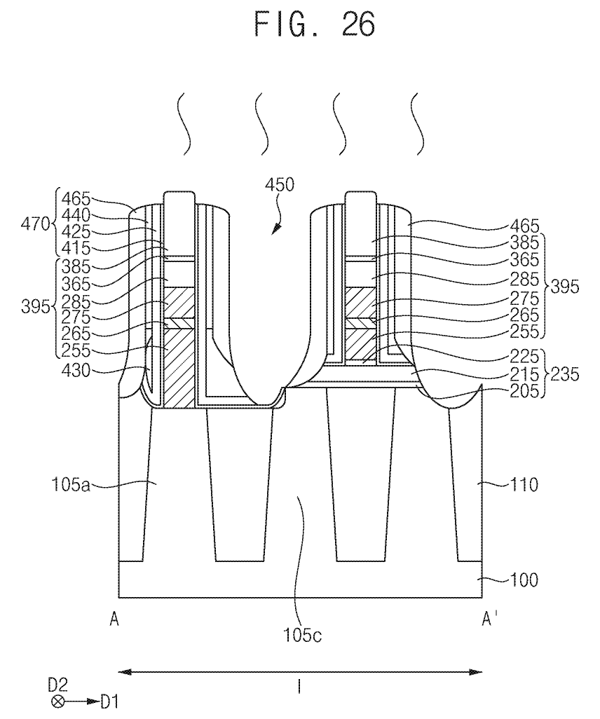

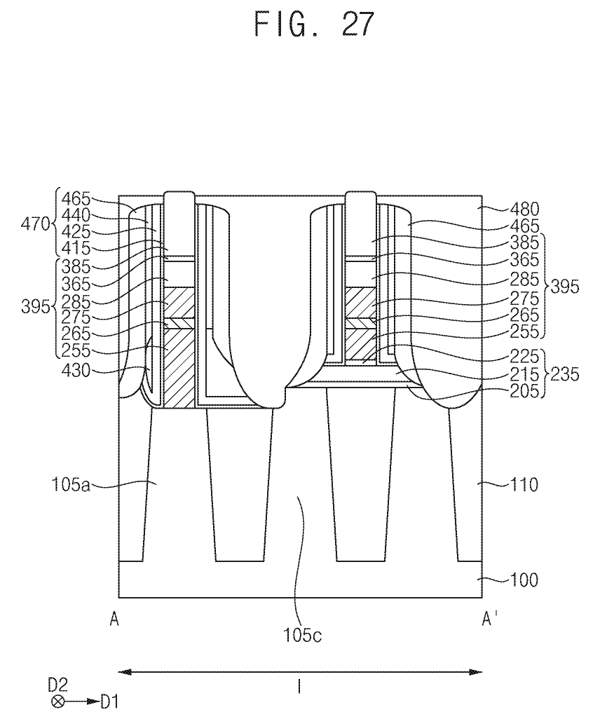

Referring to FIG. 26, an ion implantation process or a doping process may be performed on the first and second regions I and II of the substrate 100 so that upper portions of the first capping pattern 385 and the first to fourth spacers 415, 425, 440 and 465, a portion of the first spacer 415 exposed by the third opening 450, and upper portions of the isolation pattern 110 and the active pattern 105 exposed by the fourth opening 455 may include impurities, e.g., phosphorus, arsenic, silicon, etc.

In an example embodiment, the impurities may also be implanted or doped into an upper portion of the oxide layer 400.

Referring to FIG. 27, a cleaning process may be performed on the portion of the first spacer 415 exposed by the third opening 450, the oxide layer 400 under the portion of the first spacer 415, and the portion of the active pattern 105 exposed by the fourth opening 455 so that the exposed portion of the first spacer 415 and the oxide layer 400 may be removed.

The cleaning process may include, e.g., plasma native-oxide cleaning (PNC) process. The exposed portion of the first spacer 415 may include the impurities, so as to be removed by the cleaning process even without an oxide, and thus the oxide layer 400 under the first spacer 415 may be exposed to be removed by the cleaning process.

A first sacrificial layer may be formed on the substrate 100 to fill the third and fourth openings 450 and 455, and may be planarized until the upper surface of the first capping pattern 385 is exposed to form a first sacrificial pattern 480 in each of the third and fourth openings 450 and 455.

In example embodiments, the first sacrificial pattern 480 may extend in the second direction D2, and a plurality of first sacrificial patterns 480 may be spaced apart from each other in the first direction D1 by the bit line structures 395. The first sacrificial pattern 480 may include an oxide, e.g., silicon oxide.

Referring to FIGS. 28 to 30, a second mask including a plurality of fifth openings, each of which may extend in the first direction D1, spaced apart from each other in the second direction D2 may be formed on the first capping pattern 385, the first sacrificial pattern 480 and the spacer structure 470, and the first sacrificial pattern 480 may be etched by an etching process using the second mask as an etching mask.

In example embodiments, each of the fifth openings may overlap in the vertical direction an area between the gate structures 160. By the etching process, a sixth opening exposing the upper surfaces of the active pattern 105 and the isolation pattern 110 may be formed between the bit line structures 395.

After removing the second mask, a first lower contact plug 490 may be formed in a lower portion of the sixth opening, a second lower contact plug layer may be formed to fill the sixth opening and may be planarized until the upper surfaces of the first capping pattern 385 and the first sacrificial pattern 480 are exposed to form a second lower contact plug 495. The first and second lower contact plugs 490 and 495 may collectively form a lower contact plug structure 500.

A plurality of lower contact plug structures 500 may be spaced apart from each other in the second direction D2 between the bit line structures 395. The first sacrificial pattern 480 extending in the second direction D2 between the bit line structures 395 may be divided into a plurality of parts spaced apart from each other in the second direction D2.

The first lower contact plug 490 may be formed by a selective epitaxial growth (SEG) process using the upper surface of the active pattern 105 exposed by the sixth opening, and the second lower contact plug layer may be formed by a chemical vapor deposition (CVD) process.

In example embodiments, the first lower contact plug 490 may include, e.g., single crystalline silicon, and the second lower contact plug 495 may include, e.g., amorphous polysilicon.

The first sacrificial pattern 480 may be removed to form a seventh opening, and a second capping pattern 485 may be formed to fill the seventh opening, as illustrated in FIG. 28. In example embodiments, the second capping pattern 485 may overlap the gate structure 160 in the vertical direction.

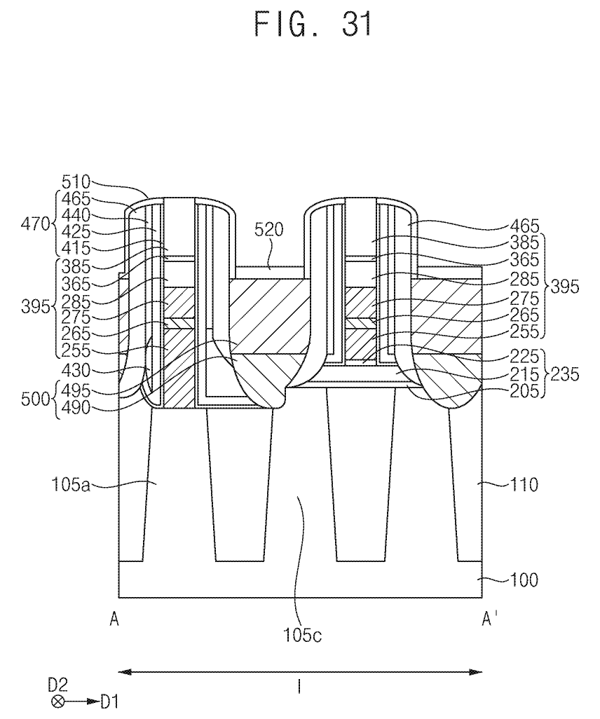

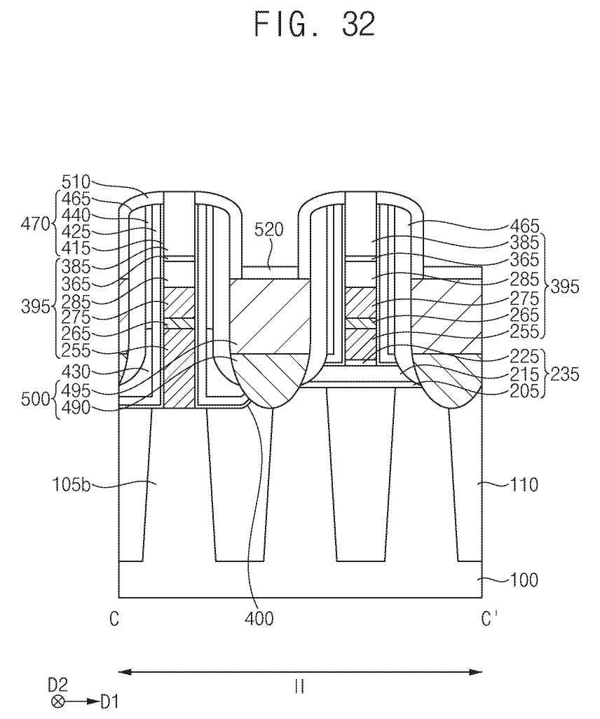

Referring to FIGS. 31 and 32, an upper portion of the second lower contact plug 495 may be removed by an etch back process.

A fifth spacer layer may be formed on the bit line structure 395, the second capping pattern 485 and the lower contact plug structure 500, and may be anisotropically etched to form a ninth spacer 510 covering an upper portion of the spacer structure 470 on each of opposite sidewalls in the first direction D1 of the bit line structure 395, and an upper surface of the lower contact plug structure 500 may be exposed.

An ohmic contact pattern 520 may be formed on the exposed upper surface of the lower contact plug structure 500. In example embodiments, the ohmic contact pattern 520 may be formed by forming a first metal layer on the first and second capping patterns 385 and 485, the ninth spacer 510 and the lower contact plug structure 500, performing a heat treatment process, and removing an unreacted portion of the first metal layer. The ohmic contact pattern 520 may include a metal silicide.

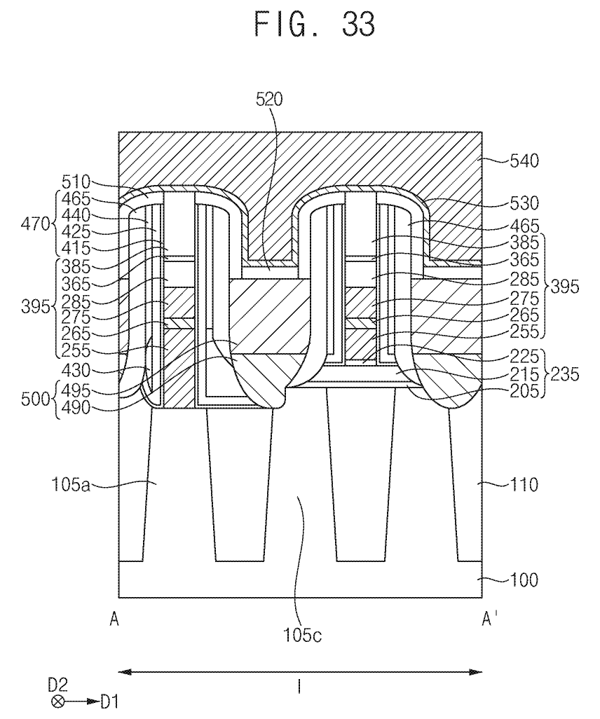

Referring to FIG. 33, a second barrier layer 530 may be formed on the first and second capping patterns 385 and 485, the ninth spacer 510, the ohmic contact pattern 520 and the lower contact plug structure 500, and a second metal layer 540 may be formed on the second barrier layer 530 to fill a space between the bit line structures 395.

A planarization process may be further performed on an upper portion of the second metal layer 540. The planarization process may include a CMP process and/or an etch back process.

Referring to FIGS. 34 to 36, the second metal layer 540 and the second barrier layer 530 may be patterned to form an upper contact plug 555, and an eighth opening 560 may be formed between the upper contact plugs 555.

The eighth opening 760 may be formed by partially removing the first and second capping patterns 385 and 485, the spacer structure 470 and the ninth spacer 510 as well as the second metal layer 540 and the second barrier layer 530.

The upper contact plug 555 may include a second metal pattern 545 and a second barrier pattern 535 covering a lower surface of the second metal pattern 545. In example embodiments, the upper contact plug 555 may have a shape of, e.g., a circle, an ellipse, a polygon, a polygon with rounded corners, etc., in a plan view, and the upper contact plugs 555 may be arranged, e.g., in a honeycomb pattern in the first and second directions D1 and D2.

The lower contact plug structure 500, the ohmic contact pattern 520 and the upper contact plug 555 sequentially stacked may collectively form a contact plug structure.

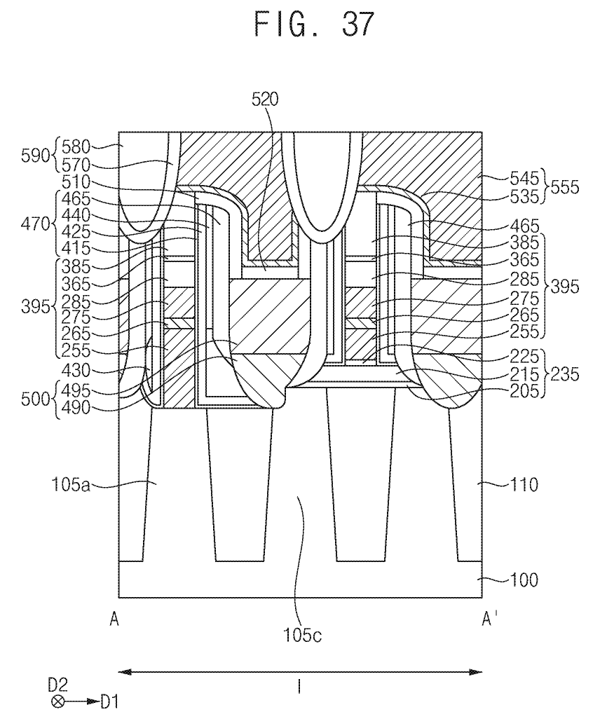

Referring to FIG. 37, a fifth insulation pattern 570 may be formed on a bottom and a sidewall of the eighth opening 560, and a sixth insulation pattern 580 may be formed to fill a remaining portion of the eighth opening 560.

The fifth and sixth insulation patterns 570 and 580 may collectively form a second insulation pattern structure 590.

In an example embodiment, the third spacer 440 of the spacer structure 470 exposed by the eighth opening 560 may be removed to form an air gap, and a top end of the air gap may be covered by the fifth insulation pattern 570.

Referring to FIGS. 1 to 3 again, a first capacitor electrode 600 may be formed to contact an upper surface of the upper contact plug 555, a dielectric pattern 610 may be formed on an upper surface and a sidewall of the first capacitor electrode 600 and an upper surface of the second insulation pattern structure 590, and a second capacitor electrode 620 may be formed on the dielectric pattern 610.

The first capacitor electrode 600, the dielectric pattern 610 and the second capacitor electrode 620 may collectively form a capacitor 630.

In example embodiments, a plurality of first capacitor electrodes 600 may be formed to be spaced apart from each other in each of the first and second directions D1 and D2, and may contact the upper surfaces of corresponding upper contact plugs 555, respectively.

A plate electrode 640 may be formed on the capacitor 630.

As illustrated above, in the method of manufacturing the semiconductor device in accordance with example embodiments, the insulation layer 230 on the first region I of the substrate 100 may be partially removed to form the first opening 240 exposing the upper surface of the first active pattern 105a and the first sidewall of the third active pattern 105c adjacent to the first active pattern 105a in the first direction D1, and the bit line structure 395 may be formed on the first opening 240. The first sidewall of the third active pattern 105c exposed by the first opening 240 may be oxidized to form the oxide layer 400.

The first and second spacer layers 415 and 425 and the fourth insulation pattern 430 may be formed on each of opposite sidewalls of the bit line structure 395 on the first opening 240, the third spacer layer may be formed on the first and second spacer layers 415 and 425 and the fourth insulation pattern 430, and the third spacer layer and the first and second spacer layers 415 and 425 may be anisotropically etched to form the first to third spacers 415, 425 and 440 and the third opening 450. The fourth spacer layer 460 may be formed on the bit line structure 395, the first and third spacers 415 and 440 and the fourth insulation pattern 430, the fourth spacer layer 460 may be anisotropically etched to form so that the third opening 450 may be enlarged downwardly, the cleaning process may be performed to remove the oxide layer 400 on the third active pattern 105c, and the SEG process may be performed using the active pattern 105 as a seed to form the first lower contact plug 490.

If the first spacer 415 is not removed during the anisotropic etching process so that the oxide layer 400 on the first sidewall of the third active pattern 105c is not removed, the oxide layer 400 may not be entirely removed by the cleaning process, and thus, the first lower contact plug 490 may not be formed by the SEG process due to the oxide layer 400 on the third active pattern 105c, or a contact area between the first lower contact plug 490 and the third active pattern 105c may be small so that a contact resistance between the first lower contact plug 490 and the third active pattern 105c may increase.

However, in example embodiments, before the cleaning process, the ion implantation process may be performed on the first region I of the substrate 100, and thus the portion of the first spacer 415 exposed by the third opening 450 may include the impurities. Thus, the portion of the first spacer 415 may be removed during the cleaning process and the oxide layer 400 under the portion of the first spacer 415 may also be removed. Accordingly, the SEG process using the upper surface of the third active pattern 105c as a seed may be easily performed, so that the first lower contact plug 490 may be formed to have a sufficiently large area on the third active pattern 105c and that the contact resistance between the first lower contact plug 490 and the third active pattern 105c may decrease.

In the method of manufacturing the semiconductor device in accordance with example embodiments, an active pattern may be formed on a substrate. A gate structure may be formed in an upper portion of the active pattern, and the gate structure may extend in a first direction parallel to an upper surface of the substrate. A bit line structure may be formed on a central portion of the active pattern, and may extend in a second direction parallel to the upper surface of the substrate and crossing the first direction. The bit line structure may include a conductive structure and an insulation structure stacked in a vertical direction perpendicular to the upper surface of the substrate. Impurities may be doped into an upper portion of the insulation structure of the bit line structure.

In example embodiments, the impurities may include phosphorus, arsenic or silicon.

In example embodiments, the active pattern may include a first active pattern and a second active pattern adjacent to the first active pattern in the first direction. When the bit line structure is formed, the first and second active patterns may be partially removed to form an opening exposing an upper surface of the first active pattern and an upper sidewall of the second active pattern, and the bit line structure may be formed in the opening. An oxide layer may be formed on the exposed upper sidewall of the second active pattern.

In example embodiments, after forming the bit line structure, a spacer structure may be formed on a sidewall of the bit line structure in the first direction. The spacer structure may include first, second, third and fourth spacers. A first portion of the first spacer may cover the oxide layer.

In example embodiments, when the spacer structure is formed, first, second and third spacers may be sequentially stacked on the first sidewall of the bit line structure. A fourth spacer layer may be formed on the bit line structure and the first, second and third spacers. An anisotropic etching process may be performed on the fourth spacer layer to form a fourth spacer. The first portion of the first spacer may be exposed by the anisotropic etching process.

In example embodiments, when the impurities are doped into the upper portion of the insulation structure of the bit line structure, an ion implantation process may be performed on the bit line structure and the spacer structure. The impurities may be implanted into upper portions of the first to fourth spacers and the exposed first portion of the first spacer.

In example embodiments, after performing the ion implantation process, a cleaning process may be performed to at least partially remove the upper portions of the first to fourth spacers, the exposed first portion of the first spacer and the oxide layer.

In example embodiments, the cleaning process may include a plasma native-oxide cleaning (PNC) process.

In example embodiments, after performing the cleaning process, a first lower contact plug including single crystalline silicon may be formed on the second active pattern. A second lower contact plug may be formed on the first lower contact plug.

In example embodiments, when the first lower contact plug is formed, a selective epitaxial growth (SEG) process may be performed using the second active pattern as a seed. When the second lower contact plug is formed, a chemical vapor deposition (CVD) process may be performed.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present disclosure as defined by the appended claims.

What is claimed is:

1. A semiconductor device comprising:
an active pattern of a substrate;
a gate structure in an upper portion of the active pattern, the gate structure extending in a first direction parallel to an upper surface of the substrate; and
a bit line structure on a central portion of the active pattern, the bit line structure extending in a second direction parallel to the upper surface of the substrate and crossing the first direction, and the bit line structure including:
a conductive structure; and
an insulation structure on the conductive structure, an upper portion of the insulation structure being doped with impurities.

2. The semiconductor device according to claim 1, wherein the impurities include phosphorus, arsenic or silicon.

3. The semiconductor device according to claim 1, further comprising a first spacer structure and a second spacer structure disposed on opposite sidewalls, respectively, of the bit line structure in the first direction.

4. The semiconductor device according to claim 3, wherein each of upper portions of the first spacer structure and the second spacer structure is doped with the impurities.

5. The semiconductor device according to claim 3, wherein a maximum width in the first direction of the first spacer structure is greater than a maximum width in the first direction of the second spacer structure.

6. The semiconductor device according to claim 3, further comprising a lower contact plug structure that contacts an end portion of the active pattern,
wherein the lower contact plug structure includes:
a first lower contact plug including single crystalline silicon; and
a second lower contact plug on the first lower contact plug, the second lower contact plug including amorphous silicon.

7. The semiconductor device according to claim 6, wherein the first spacer structure includes a first spacer, a second spacer, a third spacer, and a fourth spacer that are sequentially stacked on a first sidewall of the bit line structure, and
the second spacer structure includes a fifth spacer, a sixth spacer, a seventh spacer, and an eighth spacer that are sequentially stacked on a second sidewall of the bit line structure.

8. The semiconductor device according to claim 7, wherein each of the first spacer and the second spacer of the first spacer structure contacts the first lower contact plug, and
each of the fifth spacer and the sixth spacer contacts the eighth spacer.

9. The semiconductor device according to claim 7, further comprising:
a first insulation pattern between the second spacer and the fourth spacer, the first insulation pattern contacting the second spacer and the fourth spacer; and
a second insulation pattern between the sixth spacer and the eighth spacer, the second insulation pattern contacting the sixth spacer and the eighth spacer.

10. The semiconductor device according to claim 9, wherein the first insulation pattern contacts the first lower contact plug.

11. The semiconductor device according to claim 9, wherein the first insulation pattern and the second insulation pattern contact the third spacer and the seventh spacer, respectively.

12. A semiconductor device comprising:
an active pattern of a substrate, the substrate including a first region and a second region;
a gate structure in an upper portion of the active pattern, the gate structure extending in a first direction parallel to an upper surface of the substrate;
a bit line structure on a central portion of the active pattern, the bit line structure extending in a second direction parallel to the upper surface of the substrate and crossing the first direction;
a lower contact plug structure contacting each of end portions of the active pattern;
a first spacer structure on a first sidewall in the first direction of the bit line structure, the first spacer structure including a first spacer, a second spacer, and a third spacer that are sequentially stacked; and
a second spacer structure on a second sidewall in the first direction of the bit line structure, the second spacer structure including a fourth spacer, a fifth spacer, and a sixth spacer that are sequentially stacked,
wherein each of the first spacer and the second spacer contacts the lower contact plug structure, and
wherein each of the fourth spacer and the fifth spacer contacts the sixth spacer on the first region of the substrate.

13. The semiconductor device according to claim 12, wherein the lower contact plug structure includes:
a first lower contact plug including single crystalline silicon; and
a second lower contact plug on the first lower contact plug, the second lower contact plug including amorphous silicon, and
wherein each of the first spacer and the second spacer contacts the first lower contact plug.

14. The semiconductor device according to claim 12, wherein, on the first region of the substrate, a maximum width in the first direction of the first spacer structure is greater than a maximum width in the first direction of the second spacer structure.

15. The semiconductor device according to claim 12, wherein an upper portion of each of the first spacer and the second spacer and of the bit line structure is doped with impurities.

16. The semiconductor device according to claim 12, wherein, on the second region of the substrate, a maximum width in the first direction of the first spacer structure is substantially equal to a maximum width in the first direction of the second spacer structure.

17. The semiconductor device according to claim 12, wherein each of the third spacer and the sixth spacer contacts the lower contact plug structure.

18. A semiconductor device comprising:
active patterns of a substrate, the active patterns being spaced apart from each other in each of a first direction and a second direction that are parallel to an upper surface of the substrate and that cross each other;
gate structures each extending through first ones of the active patterns that are disposed in the first direction, the gate structures being spaced apart from each other in the second direction;
bit line structures each extending in the second direction on central portions of second ones of the active patterns that are disposed in the second direction, and each of the bit line structures including a conductive structure and an insulation structure on the conductive structure;
a first spacer structure and a second spacer structure on a first sidewall and a second sidewall, respectively, opposite to each other in the first direction of each of the bit line structures, each of the first spacer structure and the second spacer structure including an insulating material;
a contact plug structure contacting each of end portions of each of the active patterns; and
a capacitor on the contact plug structure,
wherein an upper portion of each of the first spacer structure and the second spacer structure and of an upper portion of each of the bit line structures are doped with impurities.

19. The semiconductor device according to claim 18, wherein the impurities include phosphorus, arsenic or silicon.

20. The semiconductor device according to claim 18, wherein:
the first spacer structure includes a first spacer, a second spacer, a third spacer, and a fourth spacer that are sequentially stacked,
the second spacer structure includes a fifth spacer, a sixth spacer, a seventh spacer, and an eighth spacer that are sequentially stacked, and
a lower portion of each of the first spacer and the second spacer is doped with the impurities.
